(19) United States
(12) Patent Application Publication
(10) Pub. No.: US 2025/0388807 A1
(43) Pub. Date: Dec. 25, 2025

(54) DISPLAY DEVICE

(71) Applicant: Sharp Display Technology Corporation, Kameyama City, Mie (JP)

(72) Inventor: Yuma YAGUCHI, Sakai City, Osaka (JP)

(21) Appl. No.: 18/879,419

(22) PCT Filed: Jul. 13, 2022
(86) PCT No.: PCT/JP2022/027563

§ 371 Date: Dec. 27, 2024

(51) Int. Cl. C09K 11/02; B82Y 20/00; C09D 5/22; C09D 7/20; C09D 7/40; C09D 7/62; H10K 50/115

(52) U.S. Cl. CPC C09K 11/025; C09D 5/22; C09D 7/20; C09D 7/62; C09D 7/67; H10K 50/115; B82Y 20/00

(57) ABSTRACT

A display device according to an aspect of the disclosure includes a light-emitting element comprising a nanoparticle function layer comprising at least one nanoparticle and a fluorine-containing component, in which the number of fluorine atoms constituting the fluorine-containing component is equal to or greater than the number of carbon atoms constituting the fluorine-containing component.

### TECHNICAL FIELD

The disclosure relates to a display device.

### BACKGROUND ART

PTL 1 discloses a technique in which a fluorine-containing polymer or a silane coupling agent is coordinated with quantum dots to disperse the quantum dots in a fluororesin matrix in a highly stable manner.

### CITATION LIST

### Patent Literature

PTL 1: WO 2020/241112 A1

### SUMMARY

### Technical Problem

When a dispersion in which nanoparticles such as quantum dots are dispersed contains a general hydrocarbon group or a polymer, a substance such as an organic solvent, oxygen, or moisture adheres to or comes into contact with a surface of a nanoparticle function layer such as a light-emitting layer at the time of forming the nanoparticle function layer, resulting in deterioration of the function of the nanoparticle function layer.

### Solution to Problem

To solve the above problem, a nanoparticle function layer according to a first aspect of the disclosure includes at least one nanoparticle and a fluorine-containing component, in which the number of fluorine atoms constituting the fluorine-containing component is equal to or greater than the number of carbon atoms constituting the fluorine-containing component.

A nanoparticle function layer according to a second aspect of the disclosure includes at least one nanoparticle, and a fluorine-containing component represented by the following general formula 1 and/or a fluorine-containing component represented by the following general formula 2.

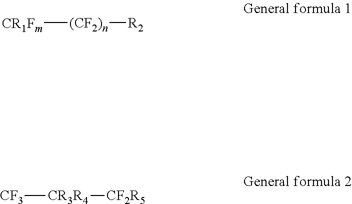

In general formula 1, R₁ and R₂ each include H, F, a hydrocarbon group, or a hydrocarbon group in which at least one hydrogen atom is exchanged with a fluorine atom, m is an integer of 0 or more, and n is an integer of 1 or more.

In general formula 2, R₃, R₄, and R₅ each include H, F, a hydrocarbon group, or a hydrocarbon group in which at least one hydrogen atom is exchanged with a fluorine atom.

A nanoparticle dispersion according to a third aspect of the disclosure is a nanoparticle dispersion including at least one nanoparticle, a fluorine-containing component, and a solvent, in which the number of fluorine atoms constituting the fluorine-containing component is equal to or greater than the number of carbon atoms constituting the fluorine-containing component.

A nanoparticle dispersion according to a fourth aspect of the disclosure is a nanoparticle dispersion including at least one nanoparticle, a fluorine-containing component represented by the following general formula 3 and/or a fluorine-containing component represented by the following general formula 4, and a solvent.

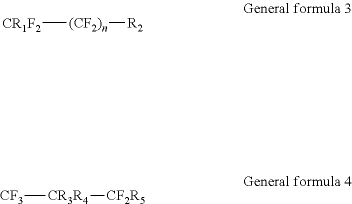

In general formula 3, R₁ and R₂ each include H, F, a hydrocarbon group, or a hydrocarbon group in which at least one hydrogen atom is exchanged with a fluorine atom, and n is an integer of 1 or more.

In general formula 4, R₃, R₄, and R₅ each include H, F, a hydrocarbon group, or a hydrocarbon group in which at least one hydrogen atom is exchanged with a fluorine atom.

Furthermore, a light-emitting element according to a fifth aspect of the disclosure includes the nanoparticle function layer according to the first aspect.

In addition, a display device according to a sixth aspect of the disclosure includes the light-emitting element according to the fifth aspect.

### Advantageous Effects of Disclosure

According to an aspect of the disclosure, it is possible to suppress adhesion or contact of a substance that deteriorates the function of the nanoparticle function layer on the surface of the nanoparticle function layer, thereby improving the efficiency and reliability of the nanoparticle function layer.

### BRIEF DESCRIPTION OF DRAWINGS

FIG. 1 is a schematic cross-sectional view of a light-emitting device according to a first embodiment of the disclosure.

FIG. 2 is a schematic enlarged view of a quantum dot and its surroundings in the schematic cross-sectional view of the light-emitting device according to the first embodiment of the disclosure.

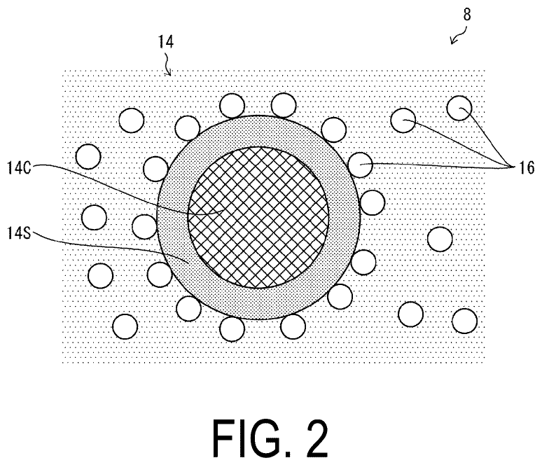

FIG. 3 is a flowchart for describing a method for manufacturing the light-emitting device according to the first embodiment of the disclosure.

FIG. 4 includes process side views for describing a method for exchanging a ligand coordinating with a quantum dot according to the first embodiment of the disclosure.

FIG. 5 is a schematic view illustrating a quantum dot dispersion according to the first embodiment of the disclosure.

FIG. 6 is a schematic view illustrating characteristics of a light-emitting layer according to the first embodiment of the disclosure.

FIG. 7 includes cross-sectional process views for describing a method for forming the light-emitting layer according to the first embodiment of the disclosure.

FIG. 8 is a schematic cross-sectional view of a display device according to a second embodiment of the disclosure.

FIG. 9 is a flowchart for describing a method for manufacturing the display device according to the second embodiment of the disclosure.

FIG. 10 is a cross-sectional process view for describing a method for forming a light-emitting layer according to the second embodiment of the disclosure.

FIG. 11 is another cross-sectional process view for describing a method for forming the light-emitting layer according to the second embodiment of the disclosure.

FIG. 12 is another cross-sectional process view for describing a method for forming the light-emitting layer according to the second embodiment of the disclosure.

FIG. 13 is another cross-sectional process view for describing a method for forming the light-emitting layer according to the second embodiment of the disclosure.

FIG. 14 is a schematic cross-sectional view of a display device according to a third embodiment of the disclosure.

FIG. 15 is a schematic cross-sectional view of a light-emitting device according to a fourth embodiment of the disclosure.

FIG. 16 is a flowchart for describing a method for manufacturing the light-emitting device according to the fourth embodiment of the disclosure.

### DESCRIPTION OF EMBODIMENTS

### First Embodiment

### Outline of Light-Emitting Device

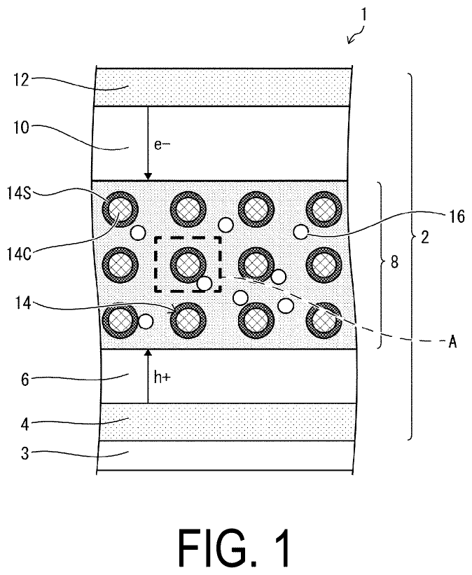

FIG. 1 is a schematic cross-sectional view of a light-emitting device as an optical device according to an embodiment of the disclosure. As illustrated in FIG. 1, a light-emitting device 1 according to the present embodiment includes a light-emitting element 2 and an array substrate 3. The light-emitting device 1 has a structure in which respective layers of the light-emitting element 2 are layered on the array substrate 3 in which a thin film transistor (TFT; not illustrated) is formed. Note that in the present specification, a direction from the light-emitting element 2 to the array substrate 3 of the light-emitting device 1 is referred to as a “downward direction”, and a direction opposite to the downward direction is referred to as an “upward direction”.

The light-emitting element 2 includes, on an anode electrode 4 as a first electrode, a hole transport layer 6, a light-emitting layer 8 (nanoparticle function layer), an electron transport layer 10, and a cathode electrode 12 as a second electrode in this order from a bottom layer. The anode electrode 4 of the light-emitting element 2 formed in an upper layer above the array substrate 3 is electrically connected to the TFT of the array substrate 3.

### Outline of Light-Emitting Element

Hereinafter, a configuration of each layer of the light-emitting element 2 will be described in more detail.

The anode electrode 4 and the cathode electrode 12 include a conductive material and are electrically connected to the hole transport layer 6 and the electron transport layer 10, respectively.

At least one of the anode electrode 4 and the cathode electrode 12 is a transparent electrode through which visible light passes. As the transparent electrode, for example, ITO, IZO, ZnO, AZO, BZO, or FTO may be used, and the transparent electrode may be formed as a film using a sputtering method or the like. Further, any one of the anode electrode 4 or the cathode electrode 12 may contain a metal material, and the metal material is preferably Al, Cu, Au, Ag, or Mg having a high reflectance of visible light, or an alloy thereof.

The hole transport layer 6 is a layer for transporting positive holes from the anode electrode 4 to the light-emitting layer 8. As the material of the hole transport layer 6, a known organic or inorganic material employed in a light-emitting element containing quantum dots (nanoparticles), an organic EL light-emitting element, or the like can be used. As the organic material of the hole transport layer 6, a conductive compound such as CBP, PPV, PEDOT-PSS, TFB, or PVK can be used. As the inorganic material of the hole transport layer 6, a metal oxide such as a molybdenum oxide, NiO, Cr₂O₃, MgO, MgZnO, LaNiO₃, or WO₃ can be used. In particular, as the material of the hole transport layer 6, a material having a large electron affinity and ionization potential is suitable.

The electron transport layer 10 is a layer for transporting electrons from the cathode electrode 12 to the light-emitting layer 8. As the material of the electron transport layer 10, in addition to TiO₂, a known organic or inorganic material employed in a light-emitting element including quantum dots, an organic EL light-emitting element, or the like can be used. As the organic material of the electron transport layer 10, a conductive compound such as Alq3, BCP, or t-Bu-PBD can be used. As the inorganic material of the electron transport layer 10, a metal oxide such as ZnO, AZO, ITO, or electride can be used. In particular, as the material of the electron transport layer 10, a material having a small electron affinity is suitable.

In the present embodiment, the hole transport layer 6 and the electron transport layer 10 can be formed using the above-described materials by a vacuum deposition method, a sputtering method, a coating formation method using a colloidal solution, or the like. The light-emitting element 2 may further include a hole injection layer between the anode electrode 4 and the hole transport layer 6, or may further include an electron injection layer between the cathode electrode 12 and the electron transport layer 10. In addition, the light-emitting element 2 may include an intermediate layer between the hole transport layer 6 and the light-emitting layer 8 or between the electron transport layer 10 and the light-emitting layer 8. Any of the hole injection layer, the electron injection layer, and the intermediate layer may be formed by the same method as the hole transport layer 6 or the electron transport layer 10.

### Light-Emitting Layer (Quantum Dot Layer)

In the present embodiment, the light-emitting layer 8 includes at least one quantum dot 14 (nanoparticle) and a fluorine-containing component 16, and the number of fluorine atoms included in the fluorine-containing component 16 is equal to or greater than the number of carbon atoms. In other words, the light-emitting layer 8 according to the present embodiment is a quantum dot layer. With this configuration, a contact angle of the light-emitting layer 8 for water can be increased. From the viewpoint of further increasing the contact angle of the light-emitting layer 8 for water, the number of fluorine atoms included in the fluorine-containing component 16 is preferably 1.6 times, and more preferably 2.0 times or more the number of carbon atoms constituting the fluorine-containing component 16. Note that in the present specification, a “quantum dot” is a dot having a maximum width of 100 nm or less. A shape of the quantum dot 14 is not particularly limited as long as it is within a range satisfying the maximum width, and the shape may be a spherical three-dimensional shape, a polygonal cross-sectional shape, or another shape.

The quantum dot 14 is, for example, a quantum dot having a core/shell structure including a core 14C and a shell 14S formed around the core 14C. In the present embodiment, recombination between an electron and a positive hole injected into the quantum dot 14 occurs mainly in the core 14C. The shell 14S has functions of suppressing generation of a defect, a dangling bond, or the like in the core 14C and reducing recombination of carriers through a deactivation process.

In the quantum dot 14, materials of the core 14C and the shell 14S may include materials used for the core material and the shell material of a quantum dot having a core/shell known in the related art, respectively.

For example, in the present embodiment, the material of the shell 14S includes ZnSₓSe₁₋ₓ where 0≤x≤1 is satisfied. Specifically, the quantum dot 14 may be a Cd-based semiconductor nanoparticle including CdSe in the core 14C and ZnS in the shell 14S. Alternatively, the quantum dot 14 may be a Cd-based semiconductor nanoparticle including CdSe in the core 14C and ZnSe in the shell 14S.

In addition, the quantum dot 14 may have CdSe/CdS, InP/ZnS, ZnSe/ZnS, CIGS/ZnS, or the like as the core/shell structure. Note that the shell 14S may be formed of a plurality of layers including a plurality of materials different from each other.

The core 14C of the quantum dot 14 is a light-emitting material that has a valence band level and a conduction band level and emits light through recombination between positive holes in the valence band level and electrons in the conduction band level. Light emitted from the quantum dot 14 has a narrow spectrum due to a quantum confinement effect, and thus it is possible to achieve light emission with relatively deep chromaticity in comparison to known light-emitting elements.

Here, the quantum dots 14 in the light-emitting layer 8 do not need to be regularly arranged as illustrated in FIG. 1, and the quantum dots 14 may be randomly included in the light-emitting layer 8. In the light-emitting layer 8 illustrated in FIG. 1, the quantum dots 14 are not in contact with each other, but this is not a limitation. The light-emitting layer may include two or more quantum dots 14 in contact with each other. Note that the thickness of the light-emitting layer 8 may be approximately from 1 nm to 100 nm.

The particle size of the quantum dot 14 is approximately from 1 nm to 100 nm. A light emission wavelength from the quantum dot 14 can be controlled by the particle size of the quantum dot. In particular, the quantum dot 14 has a core/shell structure, and thus, the wavelength of the light emitted from the quantum dot 14 can be controlled by controlling the particle size of the core 14C. Thus, the wavelength of the light emitted by the light-emitting device 1 can be controlled by controlling the particle size of the core 14C of the quantum dot 14.

In the present embodiment, the fluorine-containing component 16 included in the light-emitting layer 8 is, for example, a compound listed in Table 1. The fluorine-containing component 16 may include a plurality of compounds shown in Table 1.

TABLE 1

| Name | Structural formula |
|---|---|
| 3,3,4,4,5,5,6,6,7,7,8,8,9,9,10,10,10- heptadecafluoro-1-decanethiol | 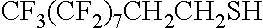 |
| 2H,2H,3H,3H- heptadecafluoroundecanoic acid | 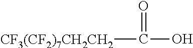 |
| 1H,1H-undecafluorohexylamine | 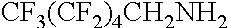 |
| Tricosafluorododecanoic acid | 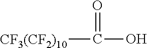 |
| Pentafluoropropionic acid | 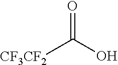 |
| Pentadecafluorooctanoic acid | 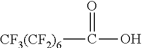 |

For example, in 3,3,4,4,5,5,6,6,7,7,8,8,9,9,10,10,10-heptadecafluoro-1-decanethiol (hereinafter referred to as compound A) shown in Table 1, the number of fluorine atoms constituting the compound A is 17, the number of carbon atoms constituting the compound A is 10, and the number of fluorine atoms constituting the compound A is equal to or greater than the number of carbon atoms constituting the compound A.

The fluorine-containing component 16 has a fluorine-containing component represented by the following general formula 1 and/or a fluorine-containing component represented by the following general formula 2.

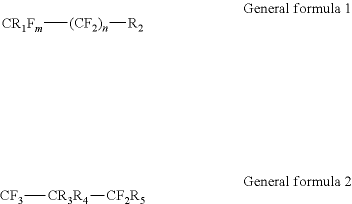

In general formula 1,
R₁ and R₂ each include H, F, a hydrocarbon group, or a hydrocarbon group in which at least one hydrogen atom is exchanged with a fluorine atom,
m is an integer of 0 or more, and n is an integer of 1 or more.

In general formula 2,
R₃, R₄, and R₅ each include H, F, a hydrocarbon group, or a hydrocarbon group in which at least one hydrogen atom is exchanged with a fluorine atom.

In the present embodiment, the fluorine-containing component 16 may or does not need to be coordinated with the quantum dot 14. Preferably, the fluorine-containing component 16 is coordinated with the quantum dot 14 as a ligand. As a result, the light-emitting layer 8 has low affinity for an organic solvent and a degradation factor such as O₂ or H₂O. Accordingly, the light-emitting layer 8 can have high durability, and the reliability of the light-emitting layer 8 can be further improved. In a case where the light-emitting layer 8 includes both the fluorine-containing component 16 and the quantum dot 14, it can be considered that the fluorine-containing component 16 is coordinated with the quantum dot 14.

Furthermore, a fluorous solvent to be described below may be coordinated with the quantum dot 14.

In a case where the fluorine-containing component 16 is coordinated with the quantum dot 14 as a ligand, the fluorine-containing component 16 is a modifying group having a coordinating functional group. Examples of the coordinating functional group include thiol, amine, carboxylic acid, phosphine, dithiocarboxylic acid, thiocarboxylic acid, and thionocarboxylic acid. The fluorine-containing component 16 represented by the above general formula 1 may have a coordinating functional group only in R₁, may have a coordinating functional group only in R₂, or may have a coordinating functional group in both R₁ and R₂. The fluorine-containing component 16 represented by the above general formula 2 may have a coordinating functional group only in R₃, may have a coordinating functional group only in R₄, may have a coordinating functional group only in R₅, may have a coordinating functional group in two of R₃, R₄, and R₅, or may have a coordinating functional group in all of R₃, R₄, and R₅.

When the fluorine-containing component 16 is coordinated with the quantum dot 14, a weight ratio of the modifying group of the fluorine-containing component 16 is preferably from 5 to 60 wt. % relative to the quantum dot (in other words, relative to the total weight of the quantum dot 14 and the fluorine-containing component 16). When the weight ratio of the modifying group of the fluorine-containing component 16 is less than 5 wt. % relative to the quantum dot, the function of protecting a defect of the quantum dot 14 is lowered. When the weight ratio of the modifying group of the fluorine-containing component 16 exceeds 60 wt. % relative to the quantum dot, a carrier injection property may be lowered at the time of light emission by the light-emitting layer 8. Note that the weight ratio of the modifying group of the fluorine-containing component 16 is more preferably from 10 to 40 wt. %, and most preferably from 10 to 20 wt. % relative to the quantum dot. Here, the modifying group corresponds to a so-called ligand, and a modification target of the modifying group is a quantum dot.

In the present embodiment, the light-emitting layer 8 contains 1 atom % or more of fluorine atoms.

Further, a band gap of the fluorine-containing component 16 included in the light-emitting layer 8 may be larger than a band gap of the material of the core 14C of the quantum dot 14. In this case, an exciton generated by recombination of carriers or light absorption in the core 14C of the quantum dot 14 is less likely to diffuse into the fluorine-containing component 16, and the light-emitting property of the quantum dot 14 is less likely to be inhibited.

As will be described below, in a case where the light-emitting layer 8 is formed from a quantum dot dispersion containing the quantum dots 14, a drying step of drying the quantum dot dispersion by heating may be included. Here, in the drying step, for example, a layered body including the quantum dot dispersion applied onto the hole transport layer 6 is heated to 80° C. to 500° C. Accordingly, in the present embodiment, from the viewpoint of the heat resistance of the light-emitting element 2, all the layers included in the light-emitting element 2 from the anode electrode 4 to the cathode electrode 12 may be formed as an inorganic material layer.

### Outline of Method for Manufacturing Light-Emitting Device

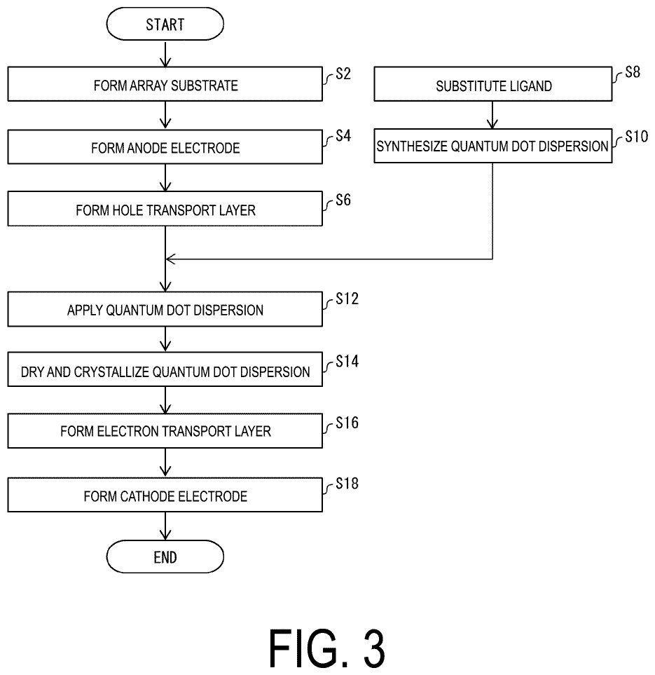

A method for manufacturing the light-emitting device 1 as an example of a method for manufacturing an optical device according to the present embodiment will be described with reference to FIG. 3. FIG. 3 is a flowchart for describing the method for manufacturing the light-emitting device 1 according to the present embodiment.

In the method for manufacturing the light-emitting device 1 according to the present embodiment, first, the array substrate 3 is formed (step S2). The array substrate 3 may be formed by forming a TFT on a glass substrate to match a position where the anode electrode 4 of the light-emitting element 2 is formed.

Next, the anode electrode 4 is formed (step S4). The anode electrode 4 may be formed by, for example, depositing a conductive material by a sputtering method or the like as described above. Next, the hole transport layer 6 is formed (step S6). As described above, the hole transport layer 6 may be formed by, for example, a vacuum deposition method, a sputtering method, or a coating formation method using a colloidal solution.

### Synthesis of Quantum Dot Dispersion

Next, the light-emitting layer 8 is formed. In the present embodiment, an example will be described in which a quantum dot dispersion (nanoparticle dispersion) containing the quantum dots 14 is synthesized, and the quantum dot dispersion is applied and then dried to obtain the light-emitting layer 8.

In the present embodiment, the quantum dot dispersion described above is, for example, a solution containing the quantum dots 14 with which the fluorine-containing component 16 is coordinated. Thus, in the present embodiment, for example, a step of obtaining the quantum dots 14 with which the fluorine-containing component 16 is coordinated is executed. To be more specific, a exchange step (step S8) of exchanging ligands coordinated with the quantum dots 14 is executed.

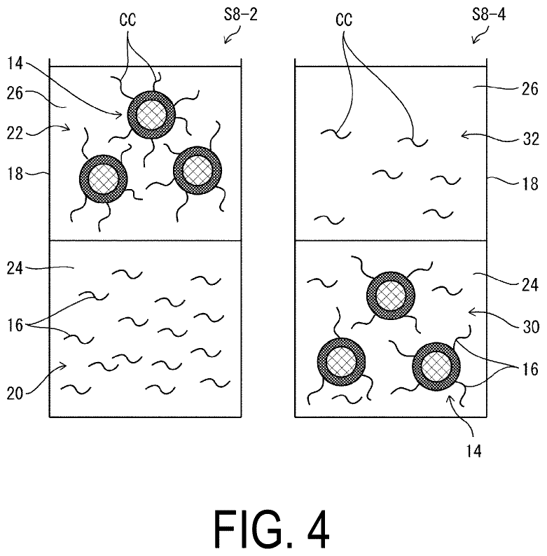

FIG. 4 includes cross-sectional process views for describing the exchange step described above. As illustrated in step S8-2 of FIG. 4, in the exchange step, first, a first solution 20 in which the fluorine-containing component 16 is dissolved and a second solution 22 in which the quantum dots 14 with which carbon chains CC (for example, dodecanethiol) as organic ligands are coordinated are dispersed are injected into a container 18. The first solution 20 includes a first solvent 24 in which the fluorine-containing component 16 is soluble, and the second solution 22 includes a second solvent 26 in which the carbon chains CC are soluble. For example, the first solvent 24 is a fluorine-containing solvent having a property of not being mixed with an organic solvent and water, and has a specific gravity higher than that of the second solvent 26.

The first solvent 24 includes one or more kinds of fluorous solvents. In the present specification, the fluorous solvent is, for example, a solvent containing a hydrocarbon in which hydrogen groups in the number exceeding carbon atoms are exchanged with fluorine. The fluorous solvent is, for example, a monomer that is a liquid in at least one temperature range included in a range of 10° C. to 180° C., is miscible with the fluorine-containing component 16 in the temperature range, and does not have a coordinating functional group. From the viewpoint of ease of handling, preferably, the fluorous solvent is a liquid in at least one temperature range included in a range of 20° C. to 60° C. and is miscible with the fluorine-containing component 16 in the temperature range. The fluorous solvent includes, for example, compounds listed in Table 2.

TABLE 2

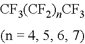

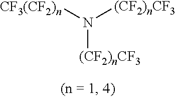

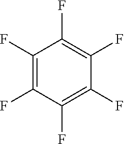 [SMILES: Fc1c(F)c(F)c(F)c(F)c1F]

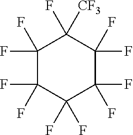 [SMILES: FC(F)(F)C1(F)C(F)(F)C(F)(F)C(F)(F)C(F)(F)C1(F)F]

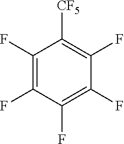

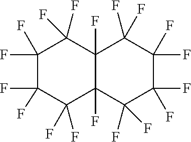 [SMILES: FC1(F)C(F)(F)C(F)(F)C2(F)C(F)(F)C(F)(F)C(F)(F)C(F)(F)C2(F)C1(F)F]

The first solvent 24 may contain at least one of organic solvents such as methanol, acetone, hexane, and toluene, in addition to the fluorous solvent.

The first solvent 24 containing the fluorous solvent effectively disperses the quantum dots 14 with which the fluorine-containing component 16 is coordinated. The second solvent 26 is desirably, for example, toluene, hexane, octane, octadecene, or the like. The second solvent 26 is desirably a solvent that can be separated from the first solvent 24.

The carbon chain CC may be a carbon chain to be generally used as a ligand of the quantum dot 14. The second solvent 26 is a solvent in which the carbon chains CC are soluble, and thus the quantum dots 14 with which the carbon chains CC are coordinated are easily dispersed in the second solution 22. In addition, the fluorine-containing component 16 is dissolved in the first solution 20 in an excessive amount exceeding the amount of the fluorine-containing component 16 capable of being coordinated with the quantum dots 14. A concentration of the fluorine-containing component 16 in the first solvent 24 is preferably 0.01 mol/l or more, and more preferably 0.1 mol/l or more.

Next, the container 18 containing the first solution 20 and the second solution 22 described above is vibrated at a high speed by a stirrer to stir the first solution 20 and the second solution 22. To improve stirring efficiency, a stirring bar may be put into the container 18. In other words, the step of stirring the first solution 20 and the second solution 22 is a step of treating the quantum dots 14 with the fluorine-containing component 16, in particular, a step of generating the quantum dots 14 with which the fluorine-containing component 16 is coordinated.

Here, as described above, the first solution 20 contains an excessive amount of the fluorine-containing component 16. In general, when two or more kinds of ligands are contained in a solution in which the quantum dots 14 are dispersed, the ligands to be coordinated with the quantum dots 14 are in an equilibrium state between the ligands in the solution. Thus, when the first solution 20 and the second solution 22 are stirred, at least a part of the ligands coordinated with the quantum dots 14 is exchanged from the carbon chains CC to the fluorine-containing component 16.

For example, in step S8, the solutions in the container 18 are stirred for at least one minute or longer. The stirring of the solutions in the container 18 may be performed at a frequency of 10 times per minute for 1 hour with the temperature of the solutions in the container 18 set to 25° C. Under such conditions, it can be said that the probability that the ligands coordinated with the quantum dots 14 in the container 18 are replaced by the fluorine-containing component 16 is sufficiently high. In addition, to prevent water, oxygen, or the like in the air from being mixed with the solutions in the container 18, it is more desirable that the solutions in the container 18 are stirred in an atmosphere of nitrogen, argon, or the like.

Accordingly, by the stirring, as illustrated in step S8-4 of FIG. 4, a third solution 30 in which the quantum dots 14 with which the fluorine-containing component 16 is coordinated are dispersed in the first solvent 24 and a fourth solution 32 in which the carbon chains CC are dissolved in the second solvent 26 are obtained in the container 18. As described above, the quantum dots 14 with which the fluorine-containing component 16 is coordinated are obtained in the third solution 30. Note that the stirring may be completed when the liquid in the container 18 is irradiated with ultraviolet light or the like and it is confirmed that the liquid layer emitting light moves from the upper side to the lower side of the container 18.

A constituent ratio of the ligands coordinated with the quantum dots 14 through step S8 is preferably the fluorine-containing component 16:the carbon chains CC of 1:0.5 to 0.0 (molar ratio), and more preferably of 1:0.3 to 0.0 (molar ratio).

Note that the above-described method for exchanging the ligands coordinated with the quantum dots 14 is an example, and other methods known in the related art may be used for the exchange of the ligands coordinated with the quantum dots 14.

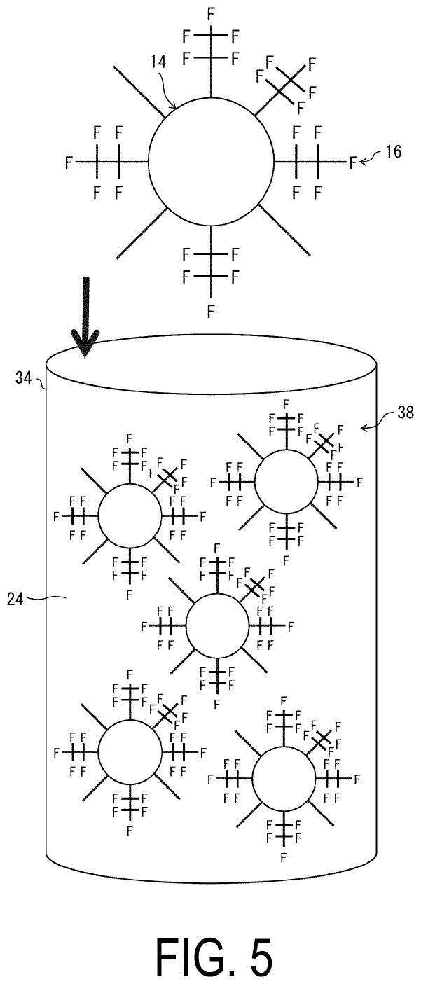

Next, a quantum dot dispersion in which the quantum dots 14 with which the fluorine-containing component 16 is coordinated are dispersed is synthesized (step S10). The quantum dot dispersion according to the present embodiment will be described in detail with reference to FIG. 5. FIG. 5 is a schematic view illustrating the quantum dot dispersion synthesized in step S10. In FIG. 5, an example of the fluorine-containing component 16 coordinated with the quantum dots 14 is schematically illustrated for easy understanding. In step S10, for example, subsequent to step S8, only the third solution 30 is extracted from the container 18 by a dropper or the like and injected into a container 34 illustrated in FIG. 5.

Here, a solution in which the fluorine-containing component 16 is dispersed in the first solvent 24 in advance may be injected into the container 18. Thus, in step S10, as illustrated in FIG. 5, a quantum dot dispersion 38 (nanoparticle functional dispersion) in which the quantum dots 14 with which the fluorine-containing component 16 is coordinated are dispersed in the first solvent 24 is synthesized.

As described above, in the present embodiment, the fluorine-containing component 16 is coordinated with the quantum dots 14 in step S8, and the quantum dot dispersion 38 containing the quantum dots 14 with which the fluorine-containing component 16 is coordinated is synthesized in step S10. In other words, step S8 and step S10 are a process of preparing the quantum dot dispersion 38. In the quantum dot dispersion 38, the quantum dots 14 are dispersed in a liquid containing the fluorine-containing component 16.

The fluorine-containing component 16 included in the quantum dot dispersion 38 is, for example, a compound listed in Table 3. The fluorine-containing component 16 included in the quantum dot dispersion 38 may contain a plurality of compounds shown in Table 3.

TABLE 3

| Name | Structural formula |
|---|---|
| 3,3,4,4,5,5,6,6,7,7,8,8,9,9,10,10,10- heptadecafluoro-1-decanethiol | 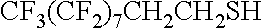 |
| 2H,2H,3H,3H- heptadecafluoroundecanoic acid | 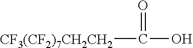 |
| 1H,1H-undecafluorohexylamine | 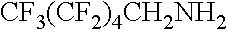 |
| Tricosafluorododecanoic acid | 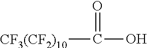 |
| Pentafluoropropionic acid | 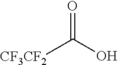 |
| Pentadecafluorooctanoic acid | 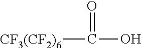 |

The quantum dot dispersion 38 contains at least one quantum dot 14, a fluorine-containing component 16 represented by the following general formula 3 and/or a fluorine-containing component 16 represented by the following general formula 4, and the first solvent 24.

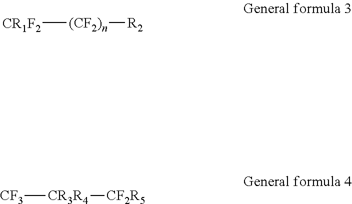

In general formula 3,
R₁ and R₂ each include H, F, a hydrocarbon group, or a hydrocarbon group in which at least one hydrogen atom is exchanged with a fluorine atom, and
n is an integer of 1 or more.

In general formula 4,
R₃, R₄, and R₅ each include H, F, a hydrocarbon group, or a hydrocarbon group in which at least one hydrogen atom is exchanged with a fluorine atom.

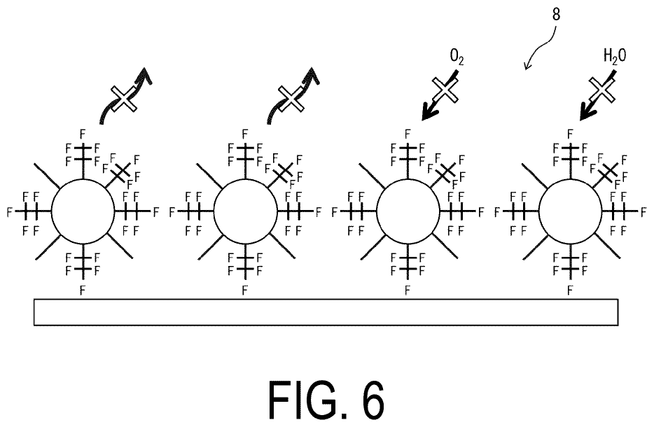

FIG. 6 is a schematic view illustrating characteristics of the light-emitting layer 8. As illustrated in FIG. 6, in the light-emitting layer 8 according to the present embodiment, contact or adhesion of oxygen or moisture to the surface of the light-emitting layer 8 is further reduced, and thus deterioration of the light-emitting layer 8 can be suppressed. In addition, detachment of the ligands from the quantum dots in the manufacturing process of the light-emitting layer 8 can be further reduced, and deterioration of the light-emitting layer in the manufacturing process can be further reduced. Thus, the efficiency of the light-emitting layer 8 can be further improved.

### Formation of Light-Emitting Layer

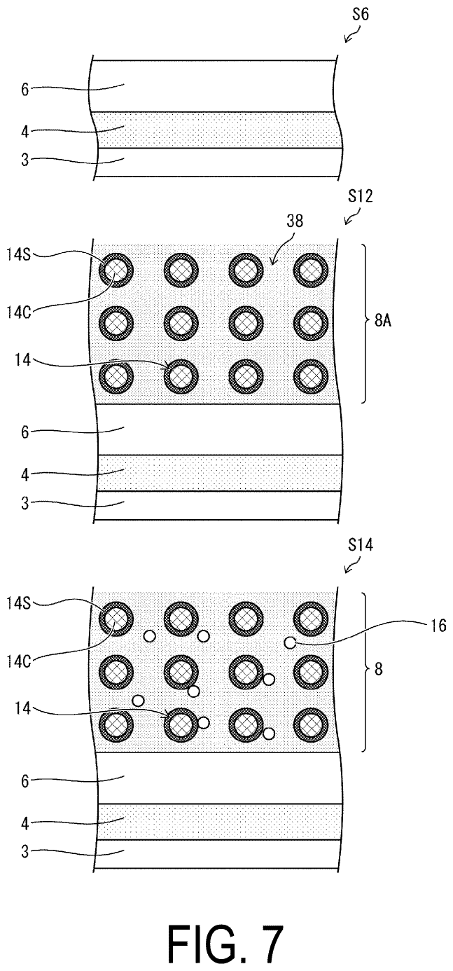

Next, a method for applying the quantum dot dispersion 38 and forming the light-emitting layer 8 from the quantum dot dispersion 38 will be described in detail with reference to FIG. 7. FIG. 7 includes cross-sectional process views for illustrating the method for forming the light-emitting layer 8.

As illustrated in FIG. 7, at the time of completion of step S6, the array substrate 3, the anode electrode 4, and the hole transport layer 6 are formed. Here, in the present embodiment, the quantum dot dispersion 38 synthesized in step S8 and step S10 is applied onto the hole transport layer 6 (step S12). In other words, step S12 is a step of applying the quantum dot dispersion 38 onto a substrate that is a layered body including the array substrate 3, the anode electrode 4, and the hole transport layer 6. This forms a coating layer 8A containing the quantum dot dispersion 38 on the hole transport layer 6.

The quantum dot dispersion 38 may be applied by, for example, a spin coating method in which the quantum dot dispersion 38 is applied onto the hole transport layer 6 while rotating the layered body from the array substrate 3 to the hole transport layer 6. Alternatively, the quantum dot dispersion 38 may be applied using an existing thin film forming method such as an inkjet method.

Subsequent to the application of the quantum dot dispersion 38, the layered body from the array substrate 3 to the coating layer 8A is heated at a temperature of 80° C. to 500° C. for 1 minute or longer to dry the coating layer 8A (step S14). Thereby, as illustrated in FIG. 7, the light-emitting layer 8 is formed on the hole transport layer 6.

In the quantum dot dispersion 38, the fluorine-containing component 16 is coordinated with the shells 14S of the quantum dots 14. Accordingly, dispersibility of the quantum dots 14 in the fluorous solvent is high, and the quantum dots 14 are less likely to precipitate. In addition, occurrence of aggregation of the quantum dots 14 is suppressed, and the dispersibility of the quantum dots 14 is maintained for a long period of time.

Furthermore, when the drying of the first solvent 24 of the quantum dot dispersion 38 proceeds from step S12 to step S14, the concentration of the quantum dots 14 in the quantum dot dispersion 38 increases. However, in the quantum dot dispersion 38, the fluorine-containing component 16 is coordinated with the shells 14S of the quantum dots 14, and thus the quantum dots 14 are prevented from being precipitated.

In step S14 according to the present embodiment, to form the light-emitting layer 8, the layered body from the anode electrode 4 to the coating layer 8A is heated to 80° C. to 500° C. Thus, all the layers from the anode electrode 4 to the cathode electrode 12 are more preferably formed as inorganic material layers.

Next, the electron transport layer 10 is formed (step S16). As described above, the electron transport layer 10 may be formed by, for example, a vacuum deposition method, a sputtering method, a coating formation method using a colloidal solution, or the like. Next, the cathode electrode 12 is formed (step S18). The cathode electrode 12 may be formed by, for example, depositing a conductive material by a sputtering method or the like as described above.

As described above, the light-emitting element 2 according to the present embodiment is formed, and the production process of the light-emitting device 1 is completed. Note that the method for manufacturing the light-emitting device 1 according to the present embodiment may include a step of forming the hole injection layer, the electron injection layer, and the intermediate layer described above. Furthermore, after step S18, a capping layer or the like may be formed on the cathode electrode 12 to form the capping layer or the like on the light-emitting element 2.

### Summary of First Embodiment

The light-emitting layer 8 according to an aspect of the disclosure includes at least one quantum dot 14 and the fluorine-containing component 16, and the number of fluorine atoms included in the fluorine-containing component 16 is equal to or greater than the number of carbon atoms. The quantum dot 14 included in the light-emitting layer 8 is encapsulated in the fluorine-containing component 16.

Accordingly, the light-emitting element 2 according to the present embodiment includes the light-emitting layer 8 having high durability. In general, the light-emitting layer of the light-emitting element is desirably smoother to reduce local concentration of carrier injection and to reduce variation in carrier injection efficiency depending on the position of the light-emitting layer 8. Thus, in the light-emitting element 2, for example, variation in carrier injection efficiency depending on the position of the light-emitting layer 8 is reduced, and higher light-emitting efficiency and improvement in lifetime are realized. In addition, the light-emitting layer 8 according to the present embodiment can protect the quantum dot 14 by the fluorine-containing component 16, which realizes the light-emitting element 2 having higher reliability.

In the present embodiment, the light-emitting layer 8 contains 1 atom % or more of fluorine atoms. According to this configuration, contact or adhesion of oxygen or moisture to the surface of the light-emitting layer is further reduced, and thus deterioration of the light-emitting layer can be suppressed. In addition, according to the above-described configuration, it is possible to further reduce detachment of the ligands from the quantum dots in the manufacturing process of the light-emitting layer and to further reduce deterioration of the light-emitting layer in the manufacturing process, and thus it is possible to further increase the efficiency of the light-emitting layer.

Furthermore, in the present embodiment, the band gap of the fluorine-containing component 16 is larger than the band gap of the core material of the quantum dot 14. According to this configuration, it is possible to realize the light-emitting layer 8 in which diffusion of excitons from the quantum dots 14 to the fluorine-containing component 16 is suppressed and the light-emitting efficiency is improved.

The method for forming the light-emitting layer 8 which is a quantum dot layer according to the present embodiment includes a step of applying the quantum dot dispersion 38 in which the quantum dots 14 are dispersed in a liquid containing the fluorine-containing component 16 onto the substrate. According to this method, contact or adhesion of oxygen or moisture to the surface of the light-emitting layer is further reduced, and thus deterioration of the light-emitting layer can be suppressed. In addition, according to the above-described configuration, it is possible to further reduce detachment of the ligands from the quantum dots in the manufacturing process of the light-emitting layer and to further reduce deterioration of the light-emitting layer in the manufacturing process, and thus it is possible to further increase the efficiency of the light-emitting layer.

In the method for forming the light-emitting layer 8 according to the present embodiment, the step of forming the light-emitting layer 8 from the quantum dot dispersion 38 may include a step of drying the applied quantum dot dispersion 38. In the step, the substrate coated with the quantum dot dispersion 38 is heated at a temperature of 80° C. to 500° C. for 1 minute or longer. In this case, for example, the light-emitting layer 8 can be formed more easily than in a case where the light-emitting layer 8 is formed by curing the quantum dot dispersion 38 by ultraviolet irradiation. In addition, in the present embodiment, the fluorine-containing component 16 can protect the quantum dots 14 in the step of drying the quantum dot dispersion 38, and thus the reliability of the quantum dots 14 can be further improved.

The method for forming the light-emitting layer 8 includes a step of treating the quantum dots 14 with the fluorine-containing component 16. By the step, the quantum dots 14 with which the fluorine-containing component 16 is coordinated can be easily obtained. In particular, in the method for forming the light-emitting layer 8, in the step of treating the quantum dots 14 with the fluorine-containing component 16, the quantum dots 14 with which the fluorine-containing component 16 is coordinated is generated. For example, by the step, the quantum dots 14 with which the fluorine-containing component 16 is coordinated can be easily obtained from the existing quantum dots 14 with which the organic ligands including the carbon chains CC are coordinated.

More specifically, the step of treating the quantum dots 14 with the fluorine-containing component 16 is a step of stirring the first solution which is a non-polar solution containing 0.01 mol/l or more of the fluorine-containing component 16 and the second solution which is a polar solution containing the quantum dots 14. Here, in the step, the stirring of the first solution and the second solution is executed for 1 minute or longer. More specifically, the first solution and the second solution are stirred at a solution temperature of 25° C. at a frequency of 10 times per minute for 1 hour. This can more reliably obtain the quantum dots 14 with which the fluorine-containing component 16 is coordinated.

In addition, the quantum dot dispersion 38 includes the first solvent 24 containing at least one selected from fluorous solvents as a solvent. According to this, it is possible to synthesize the quantum dot dispersion 38 in which the quantum dots 14 including the fluorine-containing component 16 can be dissolved in the solvent.

Furthermore, the fluorine-containing component 16 may be 3,3,4,4,5,5,6,6,7,7,8,8,9,9,10,10,10-heptadecafluoro-1-decanethiol or 2H,2H,3H,3H-heptadecafluoroundecanoic acid. According to this, the effect of the fluorine-containing component 16 protecting the quantum dots 14 can be further enhanced, and the light-emitting layer 8 having higher reliability can be formed.

The method for manufacturing the light-emitting device 1 described in the present embodiment as an example of the method for manufacturing an optical device includes the above-described method for forming the light-emitting layer 8. According to the manufacturing method, it is possible to manufacture the light-emitting device 1 provided with the light-emitting element 2 including the light-emitting layer 8 with further improved light-emitting properties.

Note that in the present embodiment, the light-emitting layer 8 having the quantum dots 14 and the fluorine-containing component 16 has been described as the nanoparticle function layer having the nanoparticles and the fluorine-containing component, but the nanoparticle function layer of the disclosure is not limited to the light-emitting layer 8. In an aspect of the disclosure, the electron transport layer or the hole transport layer may be a nanoparticle function layer having nanoparticles and a fluorine-containing component. For example, the electron transport layer may be a nanoparticle function layer including nanoparticles of ZnMgO, ZnO, or the like and the fluorine-containing component 16. Alternatively, the hole transport layer may be a nanoparticle function layer including nanoparticles such as NiO or Cr₂O₃ and the fluorine-containing component 16.

### Quantum Dot Layer According to Examples

Hereinafter, an example of depositing the light-emitting layer 8 according to the present embodiment will be described. Note that the present embodiment is not limited to the following examples.

### Example 1

Onto a glass substrate as a support of 25 mm square, 100 μL of a quantum dot dispersion containing 20 mg/mL of quantum dots was dropped. Spin coating was performed under conditions of 2000 rpm for 30 seconds, followed by drying on a hotplate at 100° C. for 10 minutes. As a result, a light-emitting layer having a thickness of about 20 nm was obtained.

### Second Embodiment

### Display Device

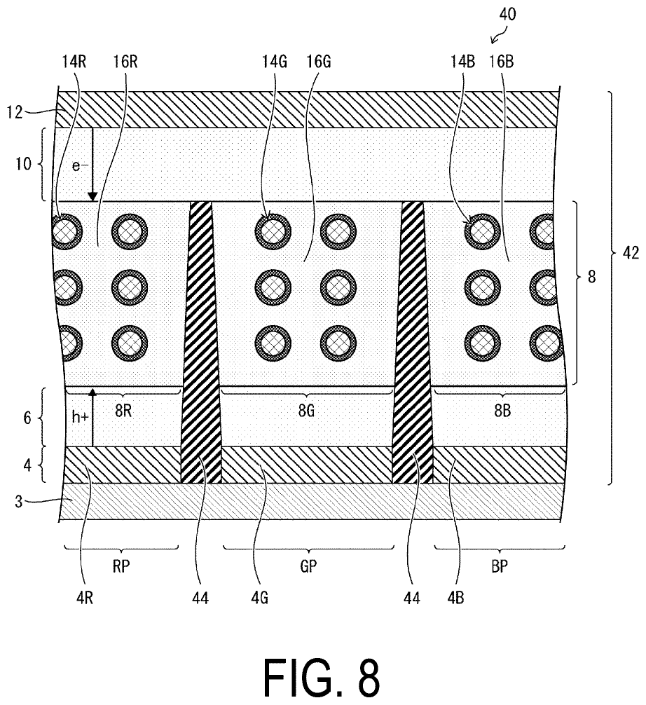

FIG. 8 is a schematic cross-sectional view of a display device 40 as an example of an optical device according to the present embodiment. The display device 40 according to the present embodiment includes a light-emitting element layer 42 on an array substrate 3. The array substrate 3 may be the same as the array substrate 3 according to the previous embodiment, but may include a TFT or the like for individually current-driving a pixel electrode to be described below.

The light-emitting element layer 42 includes a hole transport layer 6, a light-emitting layer 8, an electron transport layer 10, and a cathode electrode 12 on an anode electrode 4 in this order from a bottom layer, similarly to the light-emitting element 2 according to the previous embodiment. Here, in the present embodiment, each of the anode electrode 4, the hole transport layer 6, and the light-emitting layer 8 is separated by a bank 44.

Particularly, in the present embodiment, the anode electrode 4 is separated into an anode electrode 4R, an anode electrode 4G, and an anode electrode 4B by the bank 44. Further, the hole transport layer 6 is separated into a hole transport layer 6R, a hole transport layer 6G, and a hole transport layer 6B by the bank 44. Furthermore, the light-emitting layer 8 is separated into a red light-emitting layer 8R, a green light-emitting layer 8G, and a blue light-emitting layer 8B by the bank 44. Note that the electron transport layer 10 and the cathode electrode 12 are not separated by the bank 44 and are commonly formed. As illustrated in FIG. 5, the bank 44 separating the anode electrode 4 may be formed in a position covering a side surface and the vicinity of a peripheral end portion of an upper surface of the anode electrode 4.

Further, in the light-emitting element layer 42 according to the present embodiment, a red subpixel RP is formed of the anode electrode 4R, the hole transport layer 6R, and the red light-emitting layer 8R that have an island shape, and the electron transport layer 10 and the cathode electrode 12 that are common. Similarly, a green subpixel GP is formed of the anode electrode 4G, the hole transport layer 6G, and the green light-emitting layer 8G that have an island shape, and the electron transport layer 10 and the cathode electrode 12 that are common. Similarly, a blue subpixel BP is formed of the anode electrode 4B, the hole transport layer 6B, and the blue light-emitting layer 8B that have an island shape, and the electron transport layer 10 and the cathode electrode 12 that are common.

In the present embodiment, the red light-emitting layer 8R included in the red subpixel RP emits red light, the green light-emitting layer 8G included in the green subpixel GP emits green light, and the blue light-emitting layer 8B included in the blue subpixel BP emits blue light. That is, the light-emitting element layer 42 includes a plurality of subpixels for the respective light emission wavelengths of the light-emitting layer 8, and includes the anode electrode 4, the hole transport layer 6, and the light-emitting layer 8 for each subpixel. Note that the light-emitting element layer 42 includes the electron transport layer 10 and the cathode electrode 12 common to all of the subpixels.

Here, the blue light refers to, for example, light having an emission center wavelength in a wavelength band of equal to or greater than 400 nm and equal to or less than 500 nm. The green light refers to, for example, light having an emission center wavelength in a wavelength band of greater than 500 nm and equal to or less than 600 nm. The red light refers to, for example, light having an emission center wavelength in a wavelength band of greater than 600 nm and equal to or less than 780 nm.

In the display device 40 according to the present embodiment, one group including one red subpixel RP, one green subpixel GP, and one blue subpixel BP of the light-emitting element layer 42 is regarded as one pixel in the display device 40. Further, in the present embodiment, the display device 40 includes a plurality of pixels in addition to the above.

Each layer of the light-emitting element layer 42 according to the present embodiment may be formed of the same material as each layer of the light-emitting element 2 according to the previous embodiment except for the light-emitting layer 8. In the present embodiment, the red light-emitting layer 8R includes a red quantum dot 14R and a fluorine-containing component 16R. The green light-emitting layer 8G includes a green quantum dot 14G and a fluorine-containing component 16G. The blue light-emitting layer 8B includes a blue quantum dot 14B and a fluorine-containing component 16B.

Each of the quantum dots included in the light-emitting layer 8 may be a quantum dot having the core/shell structure including the core 14C and the shell 14S described above. In this case, the core 14C of the quantum dot included in the light-emitting layer 8 of each pixel has a different particle size depending on luminescent color. In general, in the quantum dot having the core/shell structure, the wavelength of mainly emitted light is proportional to the particle size of the core. Thus, the luminescent color of each light-emitting layer 8 can be adjusted by controlling the particle size of the core 14C of the quantum dot included in the light-emitting layer 8 of each pixel.

Each of the fluorine-containing components 16 according to the present embodiment contains the material of the fluorine-containing component 16 in the previous embodiment. Here, the fluorine-containing components 16 included in the light-emitting layers 8 in the respective subpixels may be formed of the same material or different materials between the subpixels.

### Method for Manufacturing Display Device

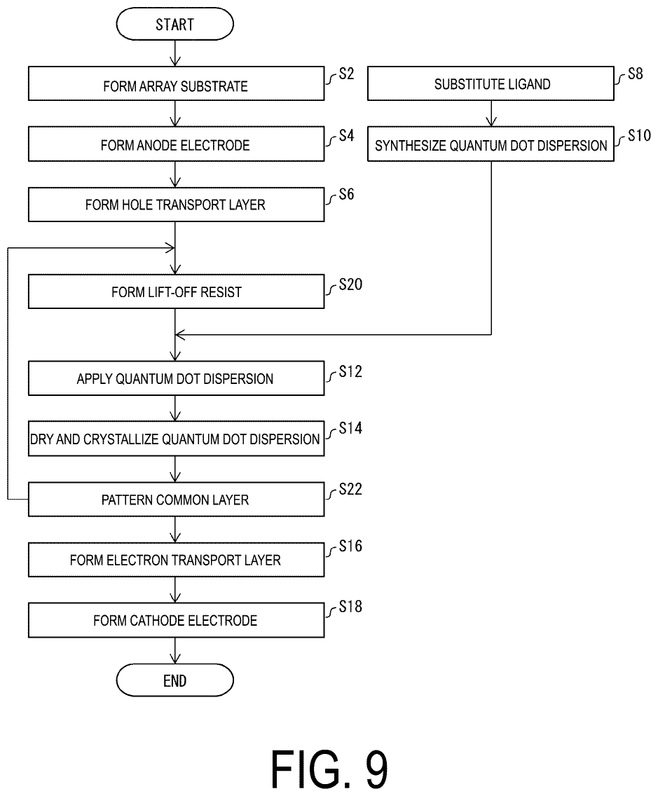

A method for manufacturing the display device 40 as an example of the method for manufacturing an optical device according to the present embodiment will be described with reference to FIG. 9. FIG. 9 is a flowchart for describing the method for manufacturing the display device 40 according to the present embodiment.

In the method for manufacturing the display device 40 according to the present embodiment, first, step S2 to step S6 described above are executed. Here, in step S2, a TFT for driving each subpixel may be formed on the array substrate 3. In step S4, the anode electrode 4 is formed in an island shape in each subpixel. Further, in step S6, prior to formation of the hole transport layer 6, the bank 44 is formed in a position covering the end portion of each of the anode electrodes 4. The bank 44 may be formed, for example, by applying a material containing a photosensitive resin, and then patterning the material by photolithography. Step S6 may include a step of removing the hole transport layer 6 on the bank 44. On the other hand, the hole transport layer 6 on the bank 44 may be left as it is and used as a layer common to the subpixels.

### Lift-Off Method

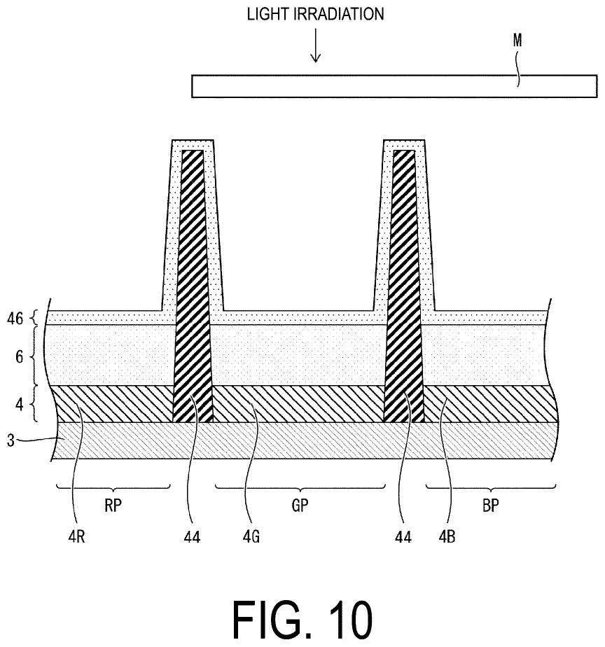

Next, a step of forming the light-emitting layer 8 is performed. The step of forming the light-emitting layer 8 according to the present embodiment will be described in more detail with reference to FIG. 10 to FIG. 13. FIG. 10 to FIG. 13 are cross-sectional process views for describing the step of forming the light-emitting layer 8 according to the present embodiment, and correspond to the cross-section of FIG. 8. Note that in FIG. 10 to FIG. 13, a method for forming the red light-emitting layer 8R will be described as an example.

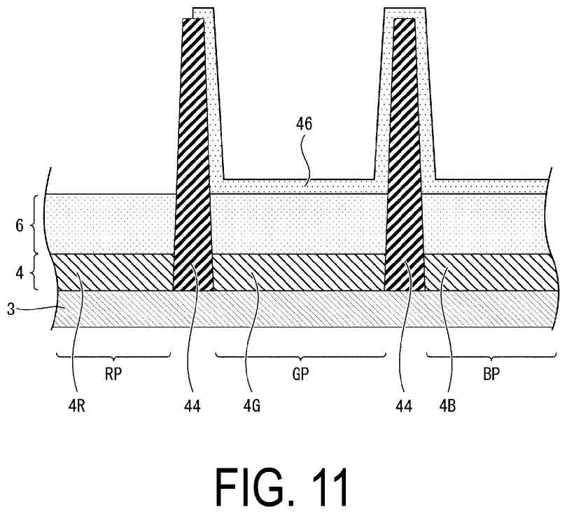

In the step of forming the light-emitting layer 8, first, as illustrated in FIG. 10 and FIG. 11, a lift-off resist 46 is patterned and formed (step S20). The lift-off resist 46 is, for example, a resin material having photosensitivity, and includes, for example, a positive-type photosensitive material in the present embodiment. In step S20, after the lift-off resist 46 is formed in common for the plurality of subpixels, the lift-off resist 46 is patterned and formed at a position other than a position where the red light-emitting layer 8R is formed by exposing and developing the lift-off resist 46.

For example, in step S20, first, as illustrated in FIG. 10, the lift-off resist 46 is formed in an upper layer above the hole transport layer 6 and the bank 44 by a coating method or the like. Next, as illustrated in FIG. 10, a photomask M is disposed above the lift-off resist 46 at a position overlapping the green subpixel GP and the blue subpixel BP except for the red subpixel RP.

In this state, as illustrated in FIG. 10, by performing light irradiation from above the lift-off resist 46, only the lift-off resist 46 formed at a position overlapping the red subpixel RP is irradiated with light. Thereby, solubility of the lift-off resist 46 formed at the position overlapping the red subpixel RP in a developing solution is improved. Next, when the lift-off resist 46 is developed with an appropriate developing solution, as illustrated in FIG. 11, the lift-off resist 46 is patterned and formed at a position overlapping the green subpixel GP and the blue subpixel BP except for the red subpixel RP. Note that prior to the patterning and formation of the lift-off resist 46, pre-baking may be executed on the applied lift-off resist 46.

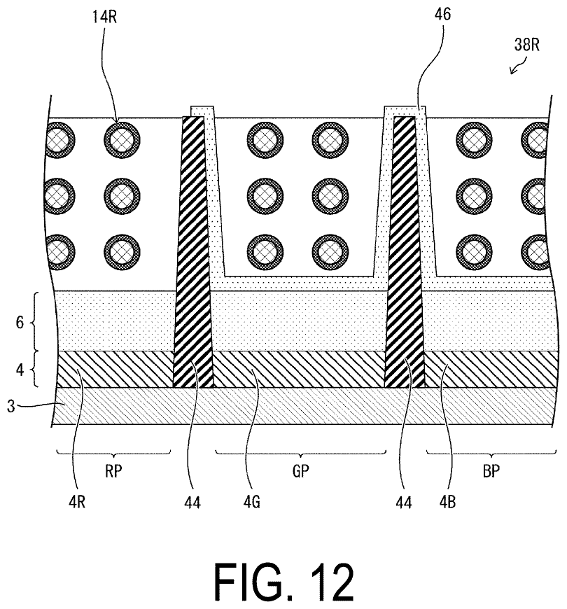

Next, as illustrated in FIG. 12, the above-described step S12 is executed to apply the quantum dot dispersion in which the quantum dots are dispersed. Note that before the execution of step S12, the above-described steps S8 and S10 are performed to synthesize the quantum dot dispersion. FIG. 12 illustrates a state in which the quantum dot dispersion 38 in which the red quantum dots 14R are dispersed is applied.

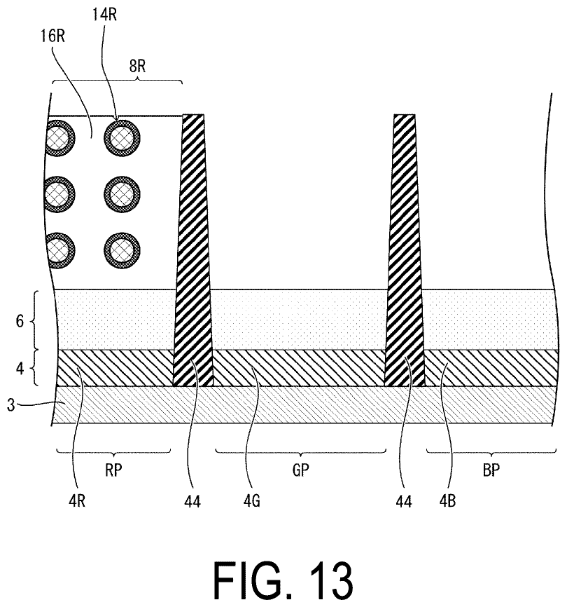

Next, the applied quantum dot dispersion is dried by the same method as step S14 described above to obtain a common layer including the red quantum dots 14R formed on each subpixel. Next, the common layer is patterned by removing a part of the common layer by a lift-off method (step S22). For example, in step S22, the lift-off resist 46 patterned and formed in step S20 is removed by an appropriate solvent containing, for example, acetone. Thus, the lift-off resist 46 formed at a position overlapping the green subpixel GP and the blue subpixel BP is removed. Here, the lift-off resist 46 is removed, and a part of the common layer formed on the lift-off resist 46 is also removed. As a result, as illustrated in FIG. 13, the red quantum dots 14R and the fluorine-containing component 16 remain only in the red subpixel RP to form the red light-emitting layer 8R.

Thereafter, step S20, step S12, step S14, and step S22 are repeatedly executed while changing the type of the quantum dots contained in the quantum dot dispersion applied in step S12 and the position where the photomask M is formed in step S20. Here, in a case where the type of the quantum dot dispersion applied in step S12 is changed, step S8 and step S10 may be executed each time the type of the quantum dot dispersion is changed. In this way, the light-emitting layer 8 including the red light-emitting layer 8R, the green light-emitting layer 8G, and the blue light-emitting layer 8B is formed.

Note that, in the present embodiment, as described above, the method for patterning and forming each light-emitting layer 8 by the lift-off method is described, but this is not a limitation. For example, in the present embodiment, each light-emitting layer 8 may be patterned by photolithography.

For example, in step S10 according to the present embodiment, a photopolymer material that is cured by ultraviolet irradiation may be added to the quantum dot dispersion 38. Next, the quantum dot dispersion 38 may be applied and dried in the same manner as in step S12 and step S14. Here, in step S14, a part of the drying of the quantum dot dispersion 38 may be performed by heating the substrate at a temperature of 80° C. to 400° C. for 1 minute or longer.

Further, after step S14, a photomask having an ultraviolet light transmitting portion at a position overlapping the red subpixel RP is placed above the quantum dot dispersion 38. Next, the quantum dot dispersion 38 is irradiated with ultraviolet light having a wavelength from 10 nm to 400 nm through the photomask for 1 minute or longer. This cures only a portion of the quantum dot dispersion 38, which overlaps the red subpixel RP. Finally, the substrate is washed with an appropriate developing solution to remove the uncured quantum dot dispersion 38 located in a portion other than the portion overlapping the red subpixel RP, thereby forming the red light-emitting layer 8R.

Next, step S12, step S14, irradiation with ultraviolet light, and developing are repeatedly performed while changing the position to be irradiated with ultraviolet light. Here, in a case where the type of the quantum dot dispersion applied in step S12 is changed, step S8 and step S10 may be executed each time the type of the quantum dot dispersion is changed. In this way, the light-emitting layer 8 including the red light-emitting layer 8R, the green light-emitting layer 8G, and the blue light-emitting layer 8B is formed.

According to the above method, execution of step S20 can be omitted. In other words, it is not necessary to pattern and form the lift-off resist 46 for each subpixel, and the light-emitting layer 8 can be directly patterned and formed, thereby simplifying the manufacturing process.

Next, steps S16 and S18 are sequentially executed to form the electron transport layer 10 and the cathode electrode 12. As described above, the light-emitting element layer 42 according to the present embodiment is formed, and the manufacturing process of the display device 40 is completed.

The light-emitting element layer 42 according to the present embodiment includes the light-emitting layer 8 containing at least one quantum dot 14 and the fluorine-containing component 16. This can protect the quantum dot 14 by the fluorine-containing component 16, and a foreign substance such as oxygen or moisture cannot come into contact with or adhere to the surface of the light-emitting layer. Thus, the light-emitting element layer 42 including the light-emitting layer 8 in which deterioration of the light-emitting function due to a foreign substance is suppressed is realized. In the present embodiment, the fluorine-containing component 16 can protect the quantum dot 14 in the step of patterning the common layer including the quantum dot 14. Accordingly, the deterioration of the quantum dot 14 due to the developing solution can be reduced, and the reliability of the quantum dot 14 can be further improved.

### Third Embodiment

### Wavelength Conversion Layer

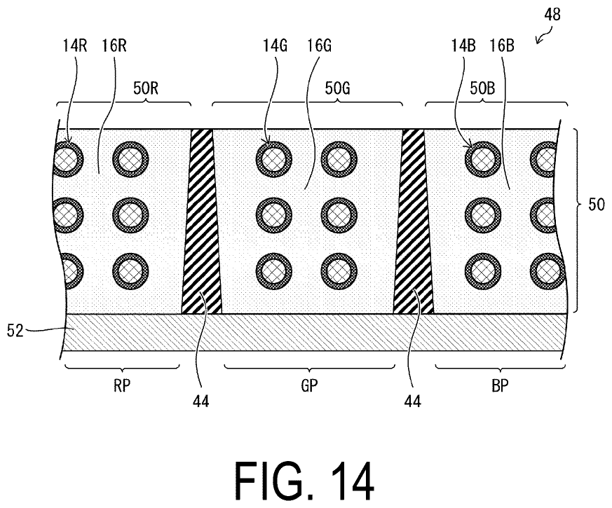

FIG. 14 is a schematic cross-sectional view of a display device 48 as another example of the optical device according to the present embodiment. The display device 48 according to the present embodiment has a configuration in which a wavelength conversion layer 50 (nanoparticle function layer) is provided on a backlight unit 52 as a light source unit.

The wavelength conversion layer 50 includes a red wavelength conversion layer 50R, a green wavelength conversion layer 50G, and a blue wavelength conversion layer 50B. Here, the red wavelength conversion layer 50R, the green wavelength conversion layer 50G, and the blue wavelength conversion layer 50B have the same configurations as the red light-emitting layer 8R, the green light-emitting layer 8G, and the blue light-emitting layer 8B according to the previous embodiment, respectively.

For example, the red wavelength conversion layer 50R includes the red quantum dot 14R and the fluorine-containing component 16R, which are described above. The green wavelength conversion layer 50G includes the green quantum dot 14G and the fluorine-containing component 16G, which are described above. The blue wavelength conversion layer 50B includes the blue quantum dot 14B and the fluorine-containing component 16B, which are described above. In other words, the wavelength conversion layer 50 according to the present embodiment is a quantum dot layer.

The red wavelength conversion layer 50R, the green wavelength conversion layer 50G, and the blue wavelength conversion layer 50B are partitioned by a bank 44 formed on the backlight unit 52 described below. The display device 48 includes a red subpixel RP at a position overlapping the red wavelength conversion layer 50R in a plan view of the backlight unit 52. Similarly, the display device 48 includes a green subpixel GP and a blue subpixel BP at positions overlapping the green wavelength conversion layer 50G and the blue wavelength conversion layer 50B, respectively, in a plan view of the backlight unit 52.

The backlight unit 52 is a light source unit that irradiates the wavelength conversion layer 50 with light. The backlight unit 52 individually irradiates, for example, the red wavelength conversion layer 50R, the green wavelength conversion layer 50G, and the blue wavelength conversion layer 50B with ultraviolet light. Accordingly, the wavelength conversion layer 50 of each subpixel irradiated with ultraviolet light from the backlight unit 52 emits light when the quantum dots 14 included therein absorb the ultraviolet light and re-emit light. Thus, the display device 48 functions as a display device having a set of the red subpixel RP, the green subpixel GP, and the blue subpixel BP as a pixel.

The display device 48 according to the present embodiment may be manufactured by the same method as the method for manufacturing the display device 40 according to the previous embodiment. For example, in the method for manufacturing the display device 48 according to the present embodiment, first, a step of preparing the backlight unit 52 is executed instead of step S2 according to the previous embodiment. Next, the bank 44 is formed on the backlight unit 52 by the same method as that described in the previous embodiment. Next, the wavelength conversion layer 50 is formed by the same method as the method for forming the light-emitting layer 8 according to the previous embodiment. As described above, the display device 48 may be manufactured.

Alternatively, the display device 48 may be manufactured by stacking the wavelength conversion layer 50 formed on a separately prepared substrate on the backlight unit 52.

The wavelength conversion layer 50 according to the present embodiment includes at least one quantum dot 14 and the fluorine-containing component 16. This can protect the quantum dot 14 by the fluorine-containing component 16, and a foreign substances such as oxygen or moisture cannot come into contact with or adhere to the surface of the light-emitting layer. Thus, the wavelength conversion layer 50 in which deterioration of the wavelength conversion function due to the foreign substance is suppressed is realized. In the present embodiment, the fluorine-containing component 16 can protect the quantum dot 14 in the step of patterning the common layer including the quantum dot 14. Accordingly, the deterioration of the quantum dot 14 due to the developing solution can be reduced, and the reliability of the quantum dot 14 can be further improved.

### Fourth Embodiment

### Light-Emitting Element Having Inverted Structure

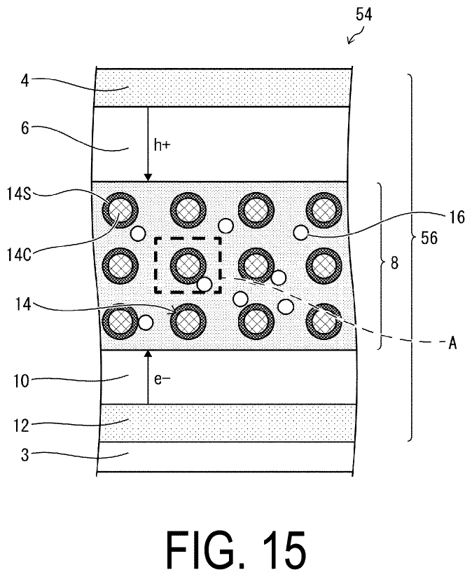

FIG. 15 is a schematic cross-sectional view of a light-emitting device as another example of an optical device according to an embodiment of the disclosure. As illustrated in FIG. 15, a light-emitting device 54 according to the present embodiment includes a light-emitting element 56 and an array substrate 3. The light-emitting element 56 includes an electron transport layer 10, a light-emitting layer 8, a hole transport layer 6, and an anode electrode 4 as a second electrode on a cathode electrode 12 as a first electrode in this order from a bottom layer. The cathode electrode 12 of the light-emitting element 56 formed in an upper layer above the array substrate 3 is electrically connected to a TFT of the array substrate 3.

The anode electrode 4, the hole transport layer 6, the light-emitting layer 8, the electron transport layer 10, and the cathode electrode 12 included in the light-emitting element 56 have the same configurations as the anode electrode 4, the hole transport layer 6, the light-emitting layer 8, the electron transport layer 10, and the cathode electrode 12 of the light-emitting element 2 according to the first embodiment, respectively, except for the stacking order of the layers.

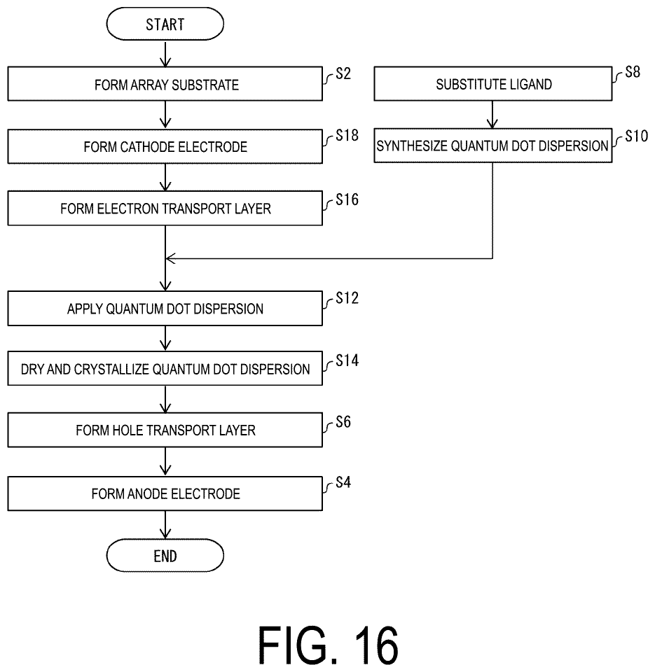

A method for manufacturing the light-emitting device 54 as an example of the method for manufacturing an optical device according to the present embodiment will be described with reference to FIG. 16. FIG. 16 is a flowchart for describing the method for manufacturing the light-emitting device 54 according to the present embodiment.

In the method for manufacturing the light-emitting device 54 according to the present embodiment, first, the array substrate 3 is formed in the same manner as step S2 described above. Next, the cathode electrode 12 is formed on the array substrate 3. The method for forming the cathode electrode 12 according to the present embodiment may be the same method as step S18 described above except that the cathode electrode 12 is formed on the array substrate 3. Next, the electron transport layer 10 is formed on the cathode electrode 12. The method for forming the electron transport layer 10 according to the present embodiment may be the same method as step S16 described above except that the electron transport layer 10 is formed on the cathode electrode 12.

In the present embodiment, before step S16 is completed, a quantum dot dispersion 38 is synthesized by the same method as that of step S8 and step S10 described above. In the present embodiment, after step S16 and step S10, the quantum dot dispersion 38 is applied onto the electron transport layer 10. The application of the quantum dot dispersion 38 according to the present embodiment may be performed by the same method as step S12 described above except that the quantum dot dispersion 38 is applied onto the electron transport layer 10. Next, drying of the quantum dot dispersion 38 is executed. The drying of the quantum dot dispersion 38 according to the present embodiment may be performed by the same method as step S14 described above except that a substrate including the array substrate 3, the cathode electrode 12, and the electron transport layer 10, and the quantum dot dispersion 38 on the substrate are heated.

Next, the hole transport layer 6 is formed on the light-emitting layer 8. The method for forming the hole transport layer 6 according to the present embodiment may be the same method as step S6 described above except that the hole transport layer 6 is formed on the light-emitting layer 8. Next, the anode electrode 4 is formed on the hole transport layer 6. The method for forming the anode electrode 4 according to the present embodiment may be the same method as step S4 described above except that the anode electrode 4 is formed on the hole transport layer 6. As described above, the light-emitting device 54 according to the present embodiment is manufactured.

The light-emitting element 56 according to the present embodiment includes the light-emitting layer 8 containing at least one quantum dot 14 and the fluorine-containing component 16. This can protect the quantum dot 14 by the fluorine-containing component 16, and a foreign substance such as oxygen or moisture cannot come into contact with or adhere to the surface of the light-emitting layer. Thus, the light-emitting element 56 including the light-emitting layer 8 in which deterioration of the light-emitting function due to the foreign substance is suppressed is realized. The light-emitting device 54 according to the present embodiment includes the light-emitting element 56 including the cathode electrode 12 on the array substrate 3 side. Thus, for example, the light-emitting element 56 can be manufactured by forming the anode electrode 4 using a transparent conductive material that is suitable for the material of the anode electrode 4 as compared with the material of the cathode electrode 12. In this case, for example, light from the light-emitting layer 8 can be extracted from the anode electrode 4 side, and thus, it is possible to realize the light-emitting device 54 capable of extracting light from the light-emitting layer 8 without considering the structure of the array substrate 3.

### Supplement

In the second and third embodiments described above, the configuration in which the light-emitting element or the wavelength conversion layer formed in one subpixel included in a certain pixel emits light of a certain luminescent color is described. However, the above-described embodiments are not limited thereto, and each light-emitting element or the wavelength conversion layer may emit white light, and a color filter formed for each subpixel may convert the white light into light of a specific color.

In this case, the light-emitting layer 8 included in the display device 40 of the second embodiment and the wavelength conversion layer 50 included in the display device 48 of the third embodiment may include all the quantum dots 14 that emit red light, green light, and blue light. In addition, the wavelength conversion layer 50 included in the display device 48 of the third embodiment may include quantum dots 14 that emit red light and green light, and the backlight unit 52 may emit blue light. In this case, the display device 48 need not include the wavelength conversion layer 50 in the blue subpixel PB.

The light-emitting device 1 according to the first embodiment, the display device 40 according to the second embodiment, and the light-emitting device 54 according to the fourth embodiment each include a light-emitting element that is one of optical elements. Here, the optical element in the present specification is not limited to the above-described light-emitting element.

For example, the optical element in the present specification may be a photovoltaic element including, between a pair of electrodes, a quantum dot layer having the same configuration as the above-described light-emitting layer 8. For example, the photovoltaic element may generate an electromotive force by generating positive holes and electrons in the quantum dot 14 from light incident on the quantum dot layer and transporting the holes and the electrons to the electrodes. Alternatively, the optical element in the present specification may be an optical sensor including the same layered body as the photovoltaic element, and in other words, may be a sensor that detects whether or not light having a specific wavelength is incident on the quantum dot layer based on whether or not the electromotive force is generated. Furthermore, the optical device in the present specification is not limited to a light-emitting device or a display device including a light-emitting element, and may be an optical device including the above-described photovoltaic element, optical sensor, or the like.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

1. A display device comprising a light-emitting element comprising a nanoparticle function layer comprising:
at least one nanoparticle; and
a fluorine-containing component,
wherein the number of fluorine atoms constituting the fluorine-containing component is equal to or greater than the number of carbon atoms constituting the fluorine-containing component.

2. The display device according to claim 1,
wherein the number of fluorine atoms constituting the fluorine-containing component is 1.6 times or more the number of carbon atoms constituting the fluorine-containing component.

3. The display device according to claim 2,
wherein the number of fluorine atoms constituting the fluorine-containing component is 2.0 times or more the number of carbon atoms constituting the fluorine-containing component.

4. The display device according to claim 1,
wherein at least one of the fluorine-containing component is a modifying group having a coordinating functional group capable of coordinating with the nanoparticle.

5. A display device comprising a light-emitting element comprising a nanoparticle function layer comprising:
at least one nanoparticle; and
a fluorine-containing component represented by general formula 1 below and/or a fluorine-containing component represented by general formula 2 below: 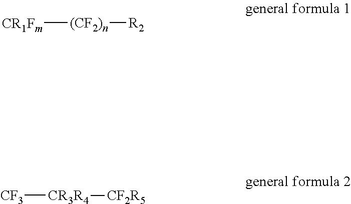
where,
in general formula 1,
R₁ and R₂ each include H, F, a hydrocarbon group, or a hydrocarbon group in which at least one hydrogen atom is exchanged with a fluorine atom,
m is an integer of 0 or more, and
n is an integer of 1 or more, and
in general formula 2,
R₃, R₄, and R₅ each include H, F, a hydrocarbon group, or a hydrocarbon group in which at least one hydrogen atom is exchanged with a fluorine atom.

6. The display device according to claim 5, comprising
the fluorine-containing component represented by general formula 1,
wherein the fluorine-containing component represented by general formula 1 is a modifying group having a coordinating functional group.

7. The display device according to claim 5- or 6, comprising
the fluorine-containing component represented by general formula 1,
wherein n is an integer of 3 or more.

8. The display device according to claim 7, comprising
the fluorine-containing component represented by general formula 1,
wherein n is 7.

9. The display device according to claim 5, comprising
the fluorine-containing component represented by general formula 1,
wherein R₁ includes a fluorine atom.

10. The display device according to claim 9, comprising
the fluorine-containing component represented by general formula 1,
wherein R₁ is F.

11. The display device according to claim 5, comprising
the fluorine-containing component represented by general formula 2,
wherein the fluorine-containing component represented by general formula 2 is a modifying group having a coordinating functional group.

12. The display device according to claim 4,
wherein a weight ratio of the modifying group is from 5 to 60 wt. % relative to a total weight of the nanoparticle and the modifying group.

13. The display device according to claim 12,
wherein the weight ratio of the modifying group is from 10 to 40 wt. % relative to the total weight of the nanoparticle and the modifying group.

14. The display device according to claim 13,
wherein the weight ratio of the modifying group is from 10 to 20 wt. % relative to the total weight of the nanoparticle and the modifying group.

15. The display device according to claim 1,
wherein the nanoparticle is a quantum dot, and
the nanoparticle function layer functions as a light-emitting layer.

16-23. (canceled)
